(19) United States
(12) Patent Application Publication
(10) Pub. No.: US 2008/0251786 A1
(43) Pub. Date: Oct. 16, 2008

(54) ORGANIC LIGHT EMITTING ELEMENT AND ORGANIC LIGHT EMITTING DEVICE

(76) Inventors: Jun-Ho CHOI, Yongin-si (KR); Jae-Kook Ha, Yongin-si (KR); Seong-Min Kim, Anyang-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/099,960

(22) Filed: Apr. 9, 2008

(30) Foreign Application Priority Data
Apr. 13, 2007 (KR) 10-2007-0036442

(51) Int. Cl. H01L 51/50

(52) U.S. Cl. 257/40; 257/E51.018

(57) ABSTRACT

An organic light emitting element according to an exemplary embodiment includes: a first electrode; a hole injection layer contacting the first electrode; a first emission layer comprising at least two sublayers emitting different color lights and contacting the hole injection layer; a first impurity layer of a first conductive type contacting the first emission layer; a second impurity layer of a second conductive type contacting the first impurity layer; a second emission layer comprising at least two sublayers emitting different color lights and contacting the second impurity layer; a electron injection layer contacting the second emission layer; and a second electrode contacting the electron injection layer.

### CROSS-REFERENCE TO RELATED APPLICATION

This application relies upon and claims priority to Korean Patent Application No. 10-2007-0036442 filed in the Korean Intellectual Property Office on Apr. 13, 2007, the contents of which are incorporated herein by reference in its entirety.

### BACKGROUND OF THE INVENTION

(a) Field of the Invention

The disclosure relates to an organic light emitting element and in particular, an organic light emitting element and an organic light emitting device including a white organic light emitting member.

(b) Description of the Related Art

An organic light emitting device includes a plurality of organic light emitting elements that include an anode, a cathode, and an organic light emitting member disposed between the anode and the cathode.

An organic light emitting element emits white light or primary-color light, and includes a light emission layer and auxiliary layers such as an electron injection layer, a hole injection layer, an electron transport layer, and a hole transport layer. A light emitting layer for an organic light emitting element generating white light has a layered structure of a plurality of light emitting materials respectively emitting three primary colors such as red, green, and blue lights.

However, such a white organic light emitting element has a low emission efficiency.

### SUMMARY OF THE INVENTION

An organic light emitting element according to one embodiment of the subject matter disclosed includes: a first electrode; a hole injection layer contacting the first electrode; a first emission layer comprising at least two sublayers emitting different color lights and contacting the hole injection layer; a first impurity layer of a first conductive type contacting the first emission layer; a second impurity layer of a second conductive type contacting the first impurity layer; a second emission layer comprising at least two sublayers emitting different color lights and contacting the second impurity layer; a electron injection layer contacting the second emission layer; and a second electrode contacting the electron injection layer.

The lights emitted by the at least two sublayers in each of the first and the second emission layers may be synthesized to form a white light.

At least one of the at least two sublayers in each of the first and the second emission layers may have a hole transport characteristic or an electron transport characteristic.

The at least two sublayers in each of the first and the second emission layers may include a first sublayer, a second sublayer, and a third sublayer that are deposited in sequence, and the second sublayer may have an emission efficiency less than the first sublayer and the third sublayer.

The first sublayer may have a hole transport characteristic and the third sublayer has an electron transport characteristic.

The first electrode may be an anode, the second electrode may be a cathode, and the first sublayer may be closer to the first electrode than the third sublayer.

The second sublayer may emit blue light, and the first sublayer and the third sublayer may emit red and green lights, respectively, or green and red lights, respectively.

The hole injection layer may include an impurity of the second conductive type and the electron injection layer comprises an impurity of the first conductive type.

The first conductive type may be n-type and the second conductive type may be p-type.

The first impurity layer may serve as an electron injection layer and the second impurity layer may serve as a hole injection layer.

An organic light emitting device according to one embodiment of the subject matter disclosed includes: an organic light emitting element comprising an anode, a cathode, and an organic light emitting member disposed between the anode and the cathode; a driving transistor connected to the organic light emitting element; a switching transistor connected to a driving transistor; a gate line connected to the switching transistor; and a data line connected to the switching transistor and insulated from the gate line, wherein the organic light emitting element comprises: a multi-layered first emission layer, a multi-layered second emission layer, a impurity junction layer disposed between the first emission layer and the second emission layer; a hole injection layer that has a first surface contacting the anode and a second surface contacting the first emission layer; and an electron injection layer that has a first surface contacting the first emission layer and a second surface contacting the cathode.

Each of the first emission layer and the second emission layer emits white light.

Each of the first emission layer and the second emission layer may include a first sublayer, a second sublayer, and a third sublayer that are deposited in sequence, and the second sublayer may have an emission efficiency less than the first sublayer and the third sublayer.

The first sublayer may have a hole transport characteristic and the third sublayer may have an electron transport characteristic, and the first sublayer may have closer to the anode than the third sublayer.

The electron injection layer and the hole injection layer may include impurity.

The impurity junction layer may include a p-type impurity layer and an n-type impurity layer contacting the p-type impurity layer.

### BRIEF DESCRIPTION OF THE DRAWINGS

FIG. 1 is an equivalent circuit of an organic light emitting device according to an exemplary embodiment;

FIG. 2 is a layout view of a pixel of an organic light emitting device according to an exemplary embodiment;

FIG. 3 is a sectional view of the organic light emitting device shown in FIG. 2 taken along line III-III; and

FIG. 4 is a schematic sectional view of an organic light emitting element according to exemplary embodiment.

### DETAILED DESCRIPTION OF THE EMBODIMENTS

The subject matter of the disclosure now will be described more fully hereinafter with reference to the accompanying drawings, in which preferred embodiments are shown.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

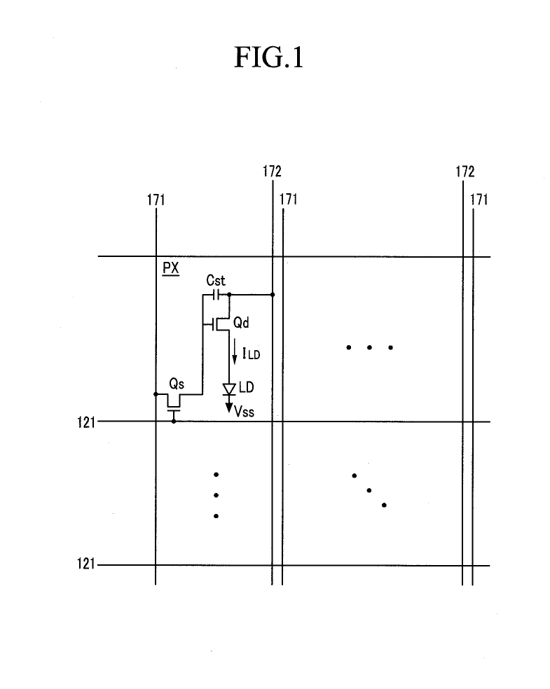

An organic light emitting device according to an exemplary embodiment will now be described in detail with reference to FIG. 1.

FIG. 1 is an equivalent circuit for an organic light emitting device according to an exemplary embodiment.

Referring to FIG. 1, an organic light emitting device includes a plurality of signal lines 121, 171 and 172, and a plurality of pixels PX connected to the signal lines 121,171 and 172 and arranged in a matrix.

The signal lines includes a plurality gate lines 121 transmitting gate signals (or scanning signals), a plurality of data lines 171 transmitting data signals, and a plurality of driving voltage lines 172 transmitting a driving voltage. The gate lines 121 extend approximately in a row direction and parallel to each other. The data lines 171 and the driving voltage lines 172 extend approximately in a column direction and parallel to each other.

Each pixel PX includes a switching transistor Qs, a driving transistor Qd, a storage capacitor Cst and an organic light emitting diode (OLED) LD.

The switching transistor Qs has a control terminal, an input terminal, and an output terminal. The control terminal is connected to a gate line 121, the input terminal is connected to a data line 171, and the output terminal is connected to the driving transistor Qd. The switching transistor Qs transmits data signals received from the data line 171 to the driving transistor Qd in response to a scanning signal from the gate lines 121.

The driving transistor Qd also has a control terminal, an input terminal, and an output terminal. The control terminal is connected to the switching transistor Qs, the input terminal is connected to the driving voltage lines 172, and the output terminal is connected to the OLED LD. The driving transistor Qd generates an output current I_{LD} having a magnitude depending on the voltage difference between the control terminal and the output terminal.

The capacitor Cst is connected between the control terminal and the input terminal of the driving transistor Qd. The capacitor Cst stores the data signals applied to the control terminal of the driving transistor Qd and maintains the signals after the switching transistor Qs turns off.

The OLED LD has an anode connected to the output terminal of the driving transistor Qd and a cathode connected to a common voltage Vss. The OLED LD emits light having an intensity depending on the output current I_{LD} of the driving transistor. This light is used to display images.

The switching transistor Qs and the driving transistor Qd are n-channel field effect transistors (FETs). However, at least one of the switching transistor Qs and the driving transistor Qd may be a p-channel FET. Moreover, relative positions of the transistors Qs and Qd, the capacitor Cst, and the OLED LD may be varied.

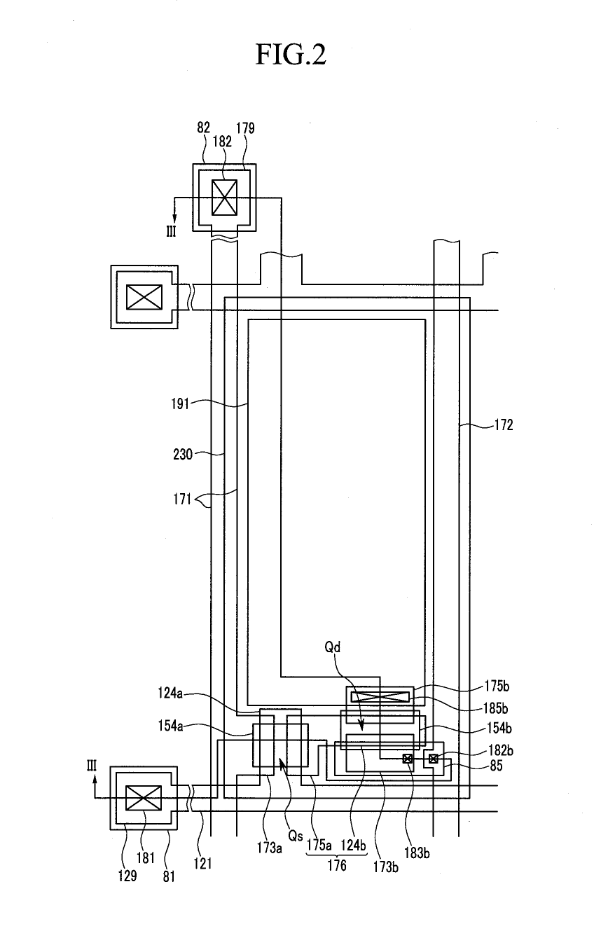

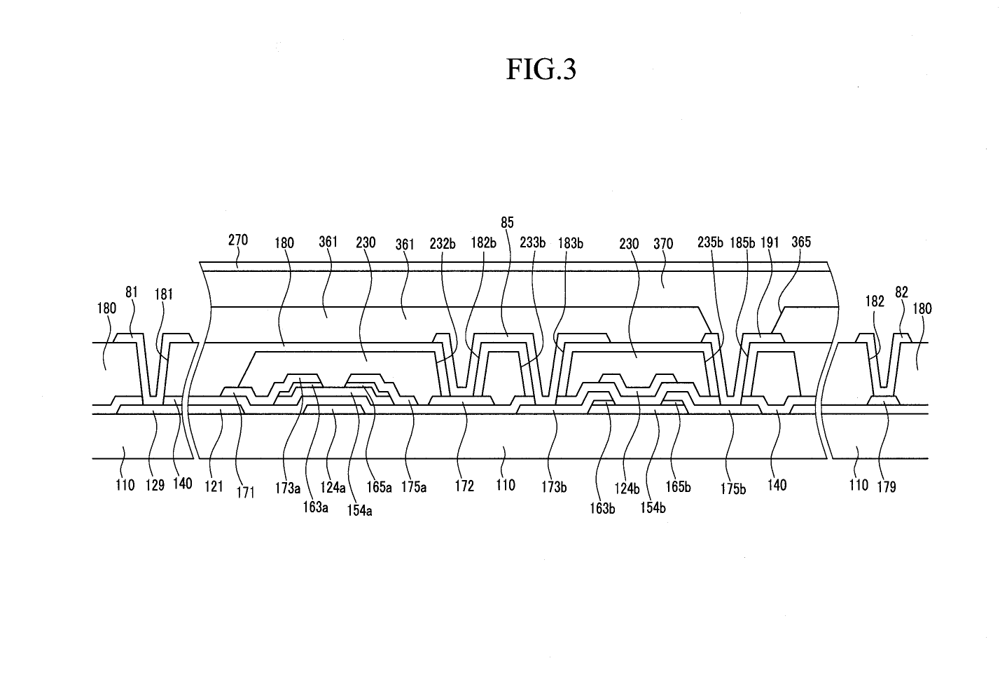

Now, a detailed structure of the organic light emitting device is described in detail with reference to FIGS. 2 and 3 as well as FIG. 1.

FIG. 2 is a layout view of a pixel of an organic light emitting device according to an exemplary embodiment, and FIG. 3 is a sectional view of the organic light emitting device shown in FIG. 2 taken along line III-III.

A plurality of semiconductor islands 154b for driving transistors (referred to as “driving semiconductor islands” hereinafter) are formed on a substrate 110. The driving semiconductor islands 154b may be made of crystalline semiconductor such as microcrystalline silicon and polycrystalline silicon.

A plurality of pairs of ohmic contact islands 163b and 165b for driving transistors (referred to as “driving ohmic contacts” hereinafter) are formed on the driving semiconductor islands 154b. The driving ohmic contacts 163b and 165b have island shapes and may be made of n+ crystalline silicon, such as microcrystalline silicon or polysilicon, heavily doped with n type impurity such as phosphorous.

A plurality of gate lines 121, a plurality of input electrodes for driving transistors (referred to as “driving input electrodes” hereinafter), and a plurality of output electrodes for driving transistors 175b (referred to as “driving output electrodes” hereinafter) are formed on the substrate 110 and the driving ohmic contacts 163b and 165b.

The gate lines 121, disposed on the substrate 110, transmit gate signals and extend approximately in a transverse direction. Each gate line 121 includes a plurality of control electrodes 124a for switching transistors (referred to as “switching control electrodes” hereinafter), which extend upward, and an end portion 129 having a large area for connection with other layer of external driving circuits.

The driving input electrodes 173b and the driving output electrodes 175b are separated from the gate lines 121 and disposed on the driving ohmic contacts 163b and 165b and the substrate 110, respectively.

A gate insulating layer 140 that may be made of silicon dioxide SiO₂ or silicon nitride SiNₓ is formed on the gate lines 121, the driving input electrodes 173b, the driving output electrodes 175b, and exposed portions of the driving semiconductor islands 154b.

A plurality of semiconductor islands 154a for switching transistors (referred to as “switching semiconductor islands” hereinafter), which may be made of hydrogenated amorphous silicon, are formed on the gate insulating layer 140. The switching semiconductor islands 154a are disposed on the switching control electrodes 124a.

A plurality of pairs of ohmic contact islands 163a and 165a for switching transistors (referred to as “switching ohmic contacts” hereinafter) are formed on the switching semiconductor islands 154a. The switching ohmic contacts 163a and 165a have island shapes and may be made of n+ hydrogenated amorphous silicon heavily doped with n type impurity such as phosphorous.

A plurality of data lines 171, a plurality of driving voltage lines 172, and a plurality of electrode members 176 are formed on the switching ohmic contacts 163a and 165a and the gate insulating layer 140.

The data lines 171 transmit data signals and extend approximately in a longitudinal direction to intersect the gate lines 121. Each of the data lines 171 includes a plurality of input electrodes 173a for switching transistors (referred to as “switching input electrodes” hereinafter), which extend toward the switching control electrodes 124a, and an end portion 179 having a large area for connection with other layer of external driving circuits.

The driving voltage lines 172 transmit a driving voltage and extend approximately in the longitudinal direction to intersect the gate lines 121.

The electrode members 176 are separated from the data lines 171 and the driving voltage lines 172. Each of the electrode members 176 includes an output electrode 175a for a switching transistor (referred to as “switching output electrode” hereinafter) and a control electrode 124b for a driving transistor (referred to as “driving control electrode” hereinafter).

The switching output electrode 175a is disposed on a switching ohmic contact 165a and the driving control electrode 124b is disposed on a driving semiconductor island 154b.

The gate lines 121, the data lines 171, the driving voltage lines 172, and the electrode members 176 may be made of the same material.

A plurality of color filters 230 are formed on the data lines 171, the driving voltage lines 172, the electrode members 176, and exposed portions of the switching semiconductor islands 154a. However, when the organic light emitting device includes white pixels, the white pixels have no color filter or have transparent white filters (not shown).

The color filters 230 have a plurality of through holes 232b, 233b, 235b. The through holes 232b expose the driving voltage lines 172, the through holes 233b exposed the driving input electrodes 173b, and the through holes 235b expose the driving output electrodes 175b.

An interlayer film (not shown) may be formed under the color filters 230. The interlayer film may prevent the pigments in the color filters 230 from intruding the switching semiconductor islands 154a.

A passivation layer 180 is formed on the color filters 230, the data lines 171, the driving voltage lines 172, and the electrode members 176.

The passivation layer 180 has a plurality of contact holes 182 exposing the end portions 179 of the data lines 171 and a plurality of contact holes 182b exposing the driving voltage lines 172 through the through holes 232b. The passivation layer 180 and the gate insulating layer 140 has a plurality of contact holes 181 exposing the end portions 129 of the gate lines 121, a plurality of contact holes 183b exposing the driving input electrodes 173b through the through holes 233b, and a plurality of contact holes 185b exposing the driving output electrodes 175b through the through holes 235b.

A plurality of pixel electrodes 191, a plurality of connecting members 85, and a plurality of contact assistants 81, 82 are formed on the passivation layer 180.

The pixel electrodes 191 are connected to the driving output electrodes 175b through the contact holes 185b.

The connecting members 85 are connected to the driving voltage lines 172 and the driving input electrodes 173b through the contact holes 182b and 183b. The connecting members 85 may overlap the driving control electrodes 124b in part to form storage capacitors Cst.

The contact assistants 81 and 82 are connected to the end portions 129 of the gate lines 121 and the end portions 179 of the data lines 171 through the contact holes 181 and 182. The contact assistants 81 and 82 enhances the adhesion between an external device and the end portions 129 and 179 of the gate lines 121 and the data lines and protects the end portions 129 and 179.

The pixel electrode 191, the connecting members 85, and the contact assistants 81 and 82 may be made of transparent conductive material such as indium-tin-oxide (ITO) or indium-zinc-oxide (IZO).

An insulating bank 361 is formed on the pixel electrodes 191 and the connecting members 85. The bank 361 surrounds boundaries of the pixel electrodes 191 to form openings 365.

A plurality of organic light emitting members 370 emitting white light are formed on the bank 361 and the pixel electrode 191, and a common electrode 270 supplied with a common voltage Vss is formed thereon.

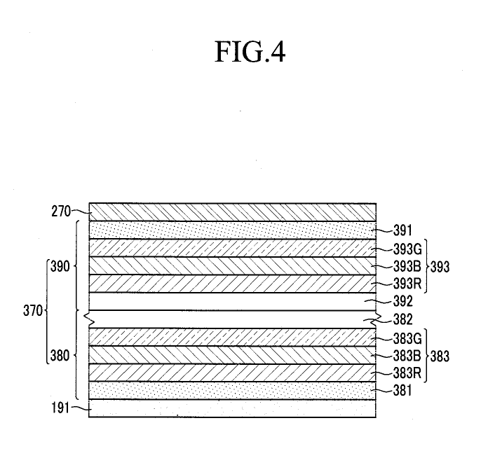

Referring to FIG. 4, the organic light emitting element 370 includes a lower emitting member 380 and an upper emitting member 390.

The lower emitting member 380 includes a hole injection layer (HIL) 381, an impurity layer 382, and an emission layer 383 interposed between the EIL 381 and the impurity layer 382. The upper emitting member 390 includes an electron injection layer (EIL) 391, an impurity layer 392, and an emission layer 393 interposed between the EIL 391 and the impurity layer 392

The HIL 381 of the lower emitting member 380 is adjacent to the pixel electrode 191 and may be doped with a p-type impurity. The impurity layer 382 is disposed opposite the HIL 381 and may be doped with an n-type impurity. The EIL 391 of the upper emitting member 390 is disposed adjacent to the common electrode 270 and may be doped with an n-type impurity. The impurity layer 392 is disposed opposite the EIL 391 and may be doped with a p-type impurity. The n-type impurity layer 382 of the lower emitting member 380 and the p-type impurity layer 392 of the upper emitting member 390 contact each other to form a impurity junction.

The p-type impurity layer 392 serves as a hole injection layer, and the n-type impurity layer 382 serves as an electron injection layers.

The HIL 381 and the p-type impurity layer 392 may be made of the same material or different materials. Likewise, the n-type impurity layer 382 and the EIL 391 may be made of the same material or different materials.

The emission layer 383/393 includes a red sublayer 383R/393R, a blue sublayer 383B/393B, and a green sublayer 383G/393G. The red sublayer 383R/393R, the blue sublayer 383B/393B, and the green sublayer 383G/393G are arranged differently according to their characteristics. Among the sublayers 383R, 383B, 383G/393R, 393B, 393G, one having the lowest emission efficiency may be disposed in the middle, another sublayer having a good hole-transport characteristic may be disposed adjacent to the pixel electrode 191, while another sublayer having a good electron-transport characteristic may be disposed adjacent to the common electrode 270. For obtaining good emission efficiency in a layered structure, the charge carriers such as electrons and holes may be distributed uniformly in the emission layer as a whole. Since the probability for finding the charge carriers is high in a middle portion, the placement of the lowest-efficiency layer in the middle can yield relatively uniform charge distribution and thus the whole emission efficiency can be made high.

FIG. 4 shows that the blue sublayer 383B/393B is disposed in the middle, because the commercially available material for the blue sublayer 383B/393B has emission efficiency lower than materials for other sublayers in the current stage. However, this structural arrangement is optional.

The positions of the red sublayer 383R/393R and the green sublayer 383G/393G shown in FIG. 4 may be exchanged, and the positions of the red sublayer 383R/393R and the green sublayer 383G/393G are different in the lower emitting member 380 and the upper emitting member 390. For example, the red sublayer 383R in the lower emitting member 380 may be disposed in the lower portion, while the red sublayer 393R in the upper emitting member 390 may be disposed in the upper portion. The opposite arrangement is also allowed.

As described above, since two emission layers 383 and 393 are layered, the emission efficiency is high.

In addition, there is no hole transport layer and no electron transport layer, and thus the structure is simple. Instead of the omission of the hole transport layer and the electron transport layer, the sublayer adjacent to the pixel electrode 191 in one of the lower and the upper emission members 380 and 390 may have a hole transport characteristic, and the sublayer close to the common electrode 270 may have an electron transport characteristic. For example, in FIG. 4, the red sublayers 383R, 393R may be made of materials having a hole transport characteristic, and the green sublayer 383G/393G may be made of materials having a electron transport characteristic.

In this organic light emitting device, the pixel electrode 191, the organic light emitting element 370, and the common electrode 270 form an OLED LD that has the pixel electrode 191 as an anode and the common electrode 270 as a cathode. However, the pixel electrode 191 may be a cathode, while the common electrode 270 may be an anode, and in this case, the internal structure of the organic light emitting element 370 is reversed relative to that shown in FIG. 4.

A switching control electrode 124a connected to a gate line 121, a switching input electrode 173a connected to a data line 171, and a switching output electrode 175a along with a switching semiconductor island 154a form a switching thin film transistor (TFT) Qs that has a channel in the switching semiconductor island 154a disposed between the switching input electrode 173a and the switching output electrode 175a.

A driving control electrode 124b connected to a switching output electrode 175a, a driving input electrode 173b connected to a driving voltage line 172, and a driving output electrode 175b connected to the pixel electrode 191 along with the driving semiconductor islands 154b form a driving TFT Qd that has a channel in the driving semiconductor island 154b disposed between the driving input electrode 173b and the driving output electrode 175b.

As described above, the switching semiconductor islands 154a are made of amorphous silicon, and the driving semiconductor islands 154b are made of crystalline semiconductor, thereby satisfying characteristics required by the TFTs. However, the semiconductor types included in the driving TFTs Qd and the switching TFTs Qs may be different from those described above. For example, both the two TFTs Qd and Qs may include amorphous silicon only or crystalline silicon only.

The driving TFTs Qd shown in FIGS. 2 and 3 have a top gate structure, and the switching TFTs Qs have a bottom gate structure. However, this structural arrangement is optional.

According to another embodiment of the present invention, each pixel PX may further include other transistors for preventing or compensating for the degradation of the OLED LD and the driving transistor Qd as well as a switching transistor Qs and a driving transistor Qd.

The subject matter disclosed herein can be employed in other types of organic light emitting devices.

Although preferred embodiments have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. An organic light emitting element comprising:
a first electrode;
a hole injection layer contacting the first electrode;
a first emission layer comprising at least two sublayers emitting different color lights and contacting the hole injection layer;
a first impurity layer of a first conductive type contacting the first emission layer;
a second impurity layer of a second conductive type contacting the first impurity layer;
a second emission layer comprising at least two sublayers emitting different color lights and contacting the second impurity layer;
a electron injection layer contacting the second emission layer; and
a second electrode contacting the electron injection layer.

2. The organic light emitting element of claim 1, wherein the lights emitted by the at least two sublayers in each of the first and the second emission layers are synthesized to form a white light.

3. The organic light emitting element of claim 1, wherein at least one of the at least two sublayers in each of the first and the second emission layers has a hole transport characteristic or an electron transport characteristic.

4. The organic light emitting element of claim 1, wherein the at least two sublayers in each of the first and the second emission layers comprise a first sublayer, a second sublayer, and a third sublayer that are deposited in sequence, and the second sublayer has an emission efficiency less than the first and the third sublayers.

5. The organic light emitting element of claim 4, wherein the first sublayer has a hole transport characteristic and the third sublayer has an electron transport characteristic.

6. The organic light emitting element of claim 5, wherein the first electrode is an anode, the second electrode is a cathode, and the first sublayer is closer to the first electrode than the third sublayer.

7. The organic light emitting element of claim 4, wherein the second sublayer emits blue light, and the first and the third sublayers emit red and green lights, respectively, or green and red lights, respectively.

8. The organic light emitting element of claim 4, wherein the hole injection layer comprises an impurity of the second conductive type and the electron injection layer comprises an impurity of the first conductive type.

9. The organic light emitting element of claim 8, wherein the first conductive type is n-type and the second conductive type is p-type.

10. The organic light emitting element of claim 9, wherein the first impurity layer serves as an electron injection layer and the second impurity layer serves as a hole injection layer.

11. An organic light emitting device comprising:
an organic light emitting element comprising an anode, a cathode, and an organic light emitting member disposed between the anode and the cathode;
a driving transistor connected to the organic light emitting element;
a switching transistor connected to a driving transistor;
a gate line connected to the switching transistor; and
a data line connected to the switching transistor and insulated from the gate line,
wherein the organic light emitting element comprises:
a multi-layered first emission layer,
a multi-layered second emission layer,
a impurity junction layer disposed between the first emission layer and the second emission layer; a hole injection layer that has a first surface contacting the anode and a second surface contacting the first emission layer; and
an electron injection layer that has a first surface contacting the first emission layer and a second surface contacting the cathode.

12. The light emitting device of claim 11, wherein each of the first and the second emission layers emits white light.

13. The light emitting device of claim 12, wherein each of the first and the second emission layers comprises a first sublayer, a second sublayer, and a third sublayer that are deposited in sequence, and the second sublayer has an emission efficiency less than the first and the third sublayers.

14. The light emitting device of claim 13, wherein the first sublayer has a hole transport characteristic and the third sublayer has an electron transport characteristic, and the first sublayer is closer to the anode than the third sublayer.

15. The light emitting device of claim 11, wherein the electron injection layer and the hole injection layer comprise impurity.

16. The light emitting device of claim 10, wherein the impurity junction layer comprises a p-type impurity layer and an n-type impurity layer contacting the p-type impurity layer.

17. An organic light emitting element comprising:
a first electrode;
a hole injection layer contacting the first electrode;
a first emission layer comprising at least two sublayers emitting different color lights and contacting the hole injection layer;
